(19) United States
(12) Patent Application Publication
(10) Pub. No.: US 2022/0216447 A1
(43) Pub. Date: Jul. 7, 2022

(54) DISPLAY SUBSTRATE, METHOD OF MANUFACTURING THE SAME, AND DISPLAY APPARATUS

(71) Applicant: BOE TECHNOLOGY GROUP CO., LTD., Beijing (CN)

(72) Inventors: Li LIU, Beijing (CN); Pengcheng LU, Beijing (CN); Kui ZHANG, Beijing (CN); Yunlong LI, Beijing (CN); Shengji YANG, Beijing (CN); Kuanta HUANG, Beijing (CN); Xiaochuan CHEN, Beijing (CN); Yuanlan TIAN, Beijing (CN); Dacheng ZHANG, Beijing (CN)

(21) Appl. No.: 17/607,015

(22) PCT Filed: Nov. 23, 2020
(86) PCT No.: PCT/CN2020/130921

§ 371 Date: Oct. 27, 2021

(30) Foreign Application Priority Data
Nov. 29, 2019 (CN) 201922114417.1

(51) Int. Cl. H01L 51/52; H01L 27/32; H01L 51/56

(52) U.S. Cl. CPC H01L 51/5209; H01L 27/3258; H01L 51/5218; H01L 2251/558; H01L 51/56; H01L 51/5265; H01L 2227/323; H01L 51/5212

(57) ABSTRACT

A display substrate is provided, including a base and a first electrode layer. The first electrode layer includes a transparent conductive layer and a reflective layer. The transparent conductive layer includes transparent conductive units that are spaced apart, a transparent conductive unit includes a flat surface and sides on peripheries, and an included angle between the flat surface and a side is an obtuse angle. The reflective layer is located on a side of the transparent conductive layer proximate to the base. The reflective layer includes reflective units that are spaced apart; the reflective units and the transparent conductive units are in one-to-one correspondence, and a reflective unit and a corresponding transparent conductive unit are electrically connected; and an orthographic projection of the reflective unit on the base is within a range of an orthographic projection of a flat surface of the corresponding transparent conductive unit on the base.

### CROSS-REFERENCE TO RELATED APPLICATIONS

This application is a national phase entry under 35 USC 371 of International Patent Application No. PCT/CN2020/130921, filed on Nov. 23, 2020, which claims priority to Chinese Patent Application No. 201922114417.1, filed on Nov. 29, 2019, which are incorporated herein by reference in their entirety.

### TECHNICAL FIELD

The present disclosure relates to the field of display technologies, and in particular, to a display substrate and a method of manufacturing the same, and a display apparatus.

### BACKGROUND

Organic light-emitting diode (OLED) display substrates have advantages of high contrast, thin thickness, wide viewing angle, fast response speed, applicability to a flexible panel, wide temperature range, and the like, and have been widely applied to smart watches, mobile phones, tablet computers, computer monitors and other devices.

### SUMMARY

In an aspect, a display substrate is provided. The display substrate includes a base and a first electrode layer disposed on a side of the base. The first electrode layer includes a transparent conductive layer and a reflective layer. The transparent conductive layer includes a plurality of transparent conductive units that are spaced apart. A transparent conductive unit includes a flat surface in a middle and side faces on peripheries, and an included angle between the flat surface and a side face is an obtuse angle. The reflective layer is located on a side of the transparent conductive layer proximate to the base. The reflective layer includes a plurality of reflective units that are spaced apart, the reflective units and the transparent conductive units are in one-to-one correspondence, and a reflective unit and a corresponding transparent conductive unit are electrically connected; and an orthographic projection of the reflective unit on the base is within a range of an orthographic projection of the flat surface of the corresponding transparent conductive unit on the base.

In some embodiments, the first electrode layer further includes: an insulating layer disposed between the reflective layer and the transparent conductive layer. The insulating layer has a plurality of via holes, and each reflective unit and the corresponding transparent conductive unit are electrically connected through a via hole.

In some embodiments, a thickness of a portion of the insulating layer located between the transparent conductive unit and the corresponding reflective unit is in a range from approximately 10 nm to approximately 500 nm.

In some embodiments, the via hole is filled with tungsten.

In some embodiments, the reflective unit includes a metal portion.

In some embodiments, a material of the metal portion includes at least one of aluminum, copper, or titanium nitride.

In some embodiments, the reflective unit further includes a first protective portion disposed on a side of the metal portion facing away from the transparent conductive layer, and/or a second protective portion disposed on a side of the metal portion proximate to the transparent conductive layer.

In some embodiments, the first protective portion includes a first protective sub-portion and/or a second protective sub-portion. A material of the first protective sub-portion includes titanium, and a material of the second protective sub-portion includes titanium nitride. The second protective portion includes a third protective sub-portion and/or a fourth protective sub-portion. A material of the third protective sub-portion includes titanium, and a material of the fourth protective sub-portion includes titanium nitride.

In some embodiments, the second protective sub-portion in the first protective portion is closer to the metal portion than the first protective sub-portion in the first protective portion; and/or, the fourth protective sub-portion in the second protective portion is closer to the metal portion than the third protective sub-portion in the second protective portion.

In some embodiments, the included angle between any side face and the flat surface of the transparent conductive unit is greater than or equal to approximately 120°.

In some embodiments, the display substrate further includes a light-emitting functional layer located on a side of the transparent conductive layer away from the reflective layer; and a second electrode layer located on a side of the light-emitting functional layer away from the transparent conductive layer.

In another aspect, a display apparatus is provided. The display apparatus includes the display substrate as described in any of the above embodiments.

In some embodiments, the display apparatus is a top-emission display apparatus.

In yet another aspect, a method of manufacturing a display substrate is provided. The method includes: providing a base; and forming a first electrode layer on a side of the base. Forming the first electrode layer on the side of the base includes: forming a reflective layer on the side of the base, the reflective layer including a plurality of reflective units that are spaced apart; and forming a transparent conductive layer on a side of the reflective layer away from the base, the transparent conductive layer including a plurality of transparent conductive units that are spaced apart; and a transparent conductive unit including a flat surface in a middle and side faces on peripheries, and an included angle between the flat surface and a side face being an obtuse angle. The reflective units and the transparent conductive units are in one-to-one correspondence, and a reflective unit and a corresponding transparent conductive unit are electrically connected; and an orthographic projection of the reflective unit on the base is within a range of an orthographic projection of the flat surface of the corresponding transparent conductive unit on the base.

In some embodiments, after forming the reflective layer and before forming the transparent conductive layer, the method further includes: forming an insulating layer on the base on which the plurality of reflective units are formed; etching the insulating layer to form a plurality of via holes exposing the plurality of reflective units; and filling tungsten in the plurality of via holes.

### BRIEF DESCRIPTION OF THE DRAWINGS

In order to describe technical solutions in the present disclosure more clearly, the accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings to be described below may be regarded as schematic diagrams, but are not limitations on an actual size of a product, and an actual process of a method involved in the embodiments of the present disclosure.

FIG. 1 is a structural diagram of a display substrate, in accordance with some embodiments;

FIG. 2 is a cross-sectional diagram of the display substrate in FIG. 1 taken along the line A-A1;

FIG. 3 is a structural diagram of another display substrate, in accordance with some embodiments;

FIG. 4 is a structural diagram of yet another display substrate, in accordance with some embodiments;

FIG. 5 is a structural diagram of yet another display substrate, in accordance with some embodiments;

FIG. 6 is a structural diagram of yet another display substrate, in accordance with some embodiments;

FIG. 7 is a structural diagram of yet another display substrate, in accordance with some embodiments;

FIG. 8 is a structural diagram of a first overcoat (or a second overcoat), in accordance with some embodiments;

FIG. 9 is a structural diagram of yet another display substrate, in accordance with some embodiments;

FIG. 10 is a structural diagram of yet another display substrate, in accordance with some embodiments;

FIG. 11 is a structural diagram of yet another display substrate, in accordance with some embodiments;

FIG. 12 is a structural diagram of a display device, in accordance with some embodiments;

FIG. 13 is a flow diagram of a method of manufacturing a display substrate, in accordance with some embodiments;

FIG. 14 is a flow diagram of another method of manufacturing a display substrate, in accordance with some embodiments; and

FIG. 15 is a flow diagram of yet another method of manufacturing a display substrate, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained on a basis of the embodiments of the present disclosure by a person of ordinary skill in the art shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Below, the terms “first” and “second” are only used for descriptive purposes, and are not to be construed as indicating or implying relative importance or implicitly indicating the number of indicated technical features. Thus, a feature defined with “first” or “second” may explicitly or implicitly include one or more of the features. In the description of the embodiments of the present disclosure, the term “a plurality of”, “the plurality of” or “multiple” means two or more unless otherwise specified.

In the description of some embodiments, the terms “coupled” and “connected” and their extensions may be used. For example, the term “connected” may be used in the description of some embodiments to indicate that two or more components are in direct physical or electrical contact with each other. As another example, the term “coupled” may be used in the description of some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the contents herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

In addition, the use of the phrase “based on” is meant to be open and inclusive, since a process, step, calculation or other action that is “based on” one or more of the stated conditions or values may, in practice, be based on additional conditions or values exceeding those stated.

The term “approximately” as used herein includes a stated value and an average value within an acceptable range of deviation of a particular value. The acceptable range of deviation is determined by a person of ordinary skill in the art in view of the measurement in question and the errors associated with the measurement of a particular quantity (i.e., the limitations of a measurement system).

Exemplary embodiments are described herein with reference to cross-sectional views and/or plan views as idealized exemplary drawings. In the accompanying drawings, thickness of layers and sizes of regions are enlarged for clarity. Therefore, variations in shape with respect to the accompanying drawings due to, for example, manufacturing technologies and/or tolerances may be envisaged. Therefore, the exemplary embodiments should not be construed as being limited to the shapes of the regions shown herein, but including deviations in the shape due to, for example, manufacturing. For example, an etched region shown in a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

In the related art, an organic light-emitting diode (OLED) display substrate includes a base and a light-emitting device layer disposed on a side of the base, and the light-emitting device layer include an anode layer, a light-emitting functional layer, and a cathode layer that are stacked. The anode layer includes a plurality of anodes that are separately disposed, and side faces of each anode form inclined side slopes, so that the light-emitting functional layer and the cathode layer are not easily broken when being evaporated subsequently. However, the inclined side slopes will make a surface of the anode uneven, which will result in poor uniformity of the light-emitting device corresponding to regions of the anode.

In order to solve the above problem, in one implementation, a pixel defining layer is provided on the anodes, the pixel defining layer covers the side slopes of the anode, and an opening of the pixel defining layer exposes an even region of the anode. In this way, the light-emitting devices do not emit light in the regions corresponding to the side to slopes of each anode, so that the opening of the pixel defining layer may be used to define a sub-pixel region of an OLED display panel to prevent cross-color in adjacent sub-pixel regions. However, the preparation of the pixel defining layer requires additional process steps, which will result in a complicated manufacturing process of the display substrate and an increase in manufacturing cost.

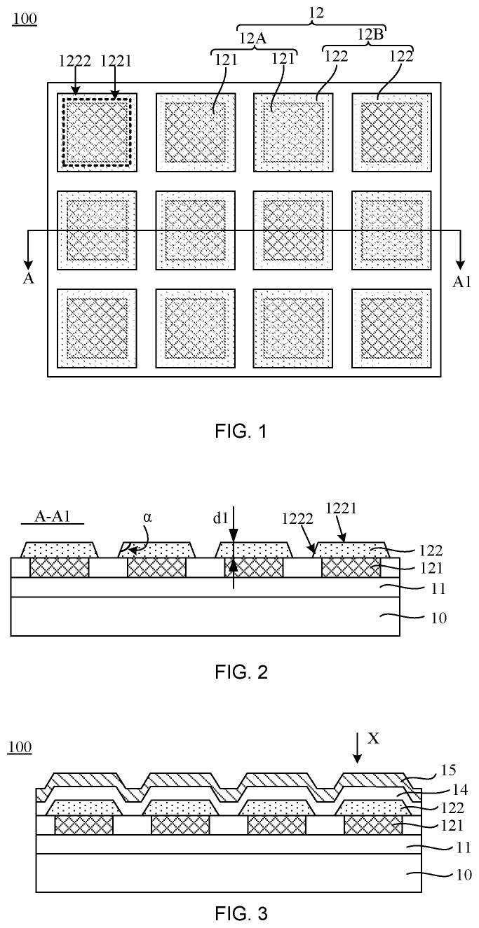

Based on this, some embodiments of the present disclosure provide a display substrate 100. Referring to FIGS. 1 and 2, the display substrate 100 includes a base 10 and a first electrode layer 12 disposed on a side of the base 10. The first electrode layer 12 may be used to replace the anode layer in the light-emitting device layer described above. On this basis, for example, as shown in FIG. 3, the display substrate 100 may further include a light-emitting functional layer 14 and a second electrode layer 15 that are sequentially disposed on a side of the first electrode layer 12 facing away from the base 10, so as to constitute light-emitting devices used to display images. It will be understood that in a case where the first electrode layer 12 is an anode layer, the second electrode layer 15 is a cathode layer.

The first electrode layer 12 includes a reflective layer 12A and a transparent conductive layer 12B that are sequentially stacked on the base 10.

The transparent conductive layer 12B includes a plurality of transparent conductive units 122 that are spaced apart. A surface of a transparent conductive unit 122 facing away from the base 10 is a raised face that is flat in a middle and inclined at obtuse angles on sides, and a flat portion of the raised face is a flat surface 1221. That is, the transparent conductive unit 122 includes the flat surface 1221 in the middle and side faces 1222 on peripheries, and an included angle between the flat surface 1221 and a side face 1222 is an obtuse angle. This arrangement enables subsequent layers (e.g., the light-emitting functional layer 14, the second electrode layer 15) to be unlikely to be broken during a formation process. In addition, the display substrate 100 may emit light uniformly in a region corresponding to the flat surface 1221.

The reflective layer 12A includes a plurality of reflective units 121 that are spaced apart. The reflective units 121 and the transparent conductive units 122 are in one-to-one correspondence, and a reflective unit 121 and a corresponding transparent conductive unit 122 are electrically connected. An orthographic projection of the reflective unit 121 on the base 10 is within a range of an orthographic projection of the flat surface 1221 of the corresponding transparent conductive unit 122 on the base 10.

This arrangement enables that the orthographic projection of the reflective unit 121 on the base 10 is not beyond the orthographic projection of the corresponding flat surface 1221 on the base 10. In this way, when the light-emitting functional layer 14 emits light, light to the first electrode layer 12 in a direction perpendicular from the light-emitting functional layer 14 to the base 10 (e.g., a direction X in FIG. 3) and a small amount of small-angle light in a direction toward the first electrode layer 12, both emitted by a portion of the light-emitting functional layer 14 that overlaps an orthographic projection of the reflective layer 12A on the base 10, may be reflected by the reflective layer 12A. Light emitted by a portion of the light-emitting functional layer 14 that does not overlap the reflective layer 12A may hardly be reflected by the reflective layer 12A. As a result, a problem of non-uniform light emission may be improved.

Moreover, when the light-emitting functional layer 14 emits light, large-angle light, emitted in the direction toward the first electrode layer 12 by the portion of the light-emitting functional layer 14 that overlaps the orthographic projection of the reflective layer 12A on the base 10 may hardly be reflected by the reflective layer 12A. Therefore, the pixel defining layer in the related art may be replaced, process steps of manufacturing the pixel defining layer may be omitted, and the manufacturing process of the display substrate 100 may be simplified, which is beneficial to lower the manufacturing cost.

In some embodiments, referring to FIGS. 2 and 3, the display substrate 100 further includes a pixel circuit layer 11 disposed between the base 10 and the first electrode layer 12. The pixel circuit layer 11 may be used to drive the light-emitting devices described above to emit light. In some examples, the pixel circuit layer 11 includes at least switching transistors, driving transistors, and storage capacitors.

In some embodiments, referring to FIGS. 1 and 2, the side faces 1222 of the transparent conductive unit 122 are also referred to as buffer surfaces 1222. The arrangement of the buffer surfaces 1222 may play a role of smooth transition, so that subsequent layers (e.g., the light-emitting functional layer 14) are not prone to breakage. It will be noted that the embodiments of the present disclosure do not limit a shape of the buffer surface 1222, as long as the buffer surface 1222 can have the smooth transition effect on the subsequent layers and prevent the subsequent layers from being broken.

For example, the included angle between any side face 1222 and the flat surface 1221 of the transparent conductive unit 122 is greater than or equal to approximately 120°. Herein, “approximately” may refer to, for example, a stated value (i.e., 120°), or it may fluctuate by ten percent up and down on a basis of the stated value (i.e., 120°). That is, the included angle α may be greater than or equal to 108°; or, the included angle α may be greater than or equal to 120°; or, the included angle α may be greater than or equal to 132°.

In some of the above embodiments, the range of the included angle between the to buffer surface 1222 and the flat surface 1221 in the raised face is greater than or equal to approximately 120°, so that the light-emitting functional layer 14 and the second electrode layer 15 may be buffered, which may prevent the light-emitting functional layer 14 and the second electrode layer 15 from being broken.

It will be noted that the embodiments of the present disclosure do not limit a material of the base 10, and the material of the base 10 may be, for example, polyimide, glass, or silicon substrate.

In some examples, the first electrode layer 12 is the anode layer, and the second electrode layer 15 is the cathode layer. In some other examples, the first electrode layer 12 is the cathode layer, and the second electrode layer 15 is the anode layer.

In some embodiments, the first electrode layer 12 is formed using a photo-etching process. On this basis, for example, chemical mechanical polishing is performed on the first electrode layer 12, so that a thickness of a region in the transparent conductive unit 122 corresponding to the flat surface 1221 may be relatively uniform.

In some examples, the display substrate 100 is applied to an OLED display apparatus, and the light-emitting functional layer 14 is an organic light-emitting functional layer. In some other examples, the display substrate 100 is applied to a quantum dot light-emitting diode (QLED) display apparatus, and the light-emitting functional layer 14 is a quantum dot light-emitting functional layer.

In some examples, the display substrate is applied to the OLED display apparatus, and the light-emitting functional layer 14 and the second electrode layer 15 may be manufactured using an evaporation process.

In some other examples, the display substrate is applied to the QLED display to apparatus, the light-emitting functional layer 14 may be formed using an ink-jet printing process, and then the second electrode layer 15 may be formed using the evaporation process.

In some embodiments, for a light-emitting device with a top light-emitting structure, the first electrode layer 12 includes not only the transparent conductive layer 12B, but also the reflective layer 12A located on a side of the transparent conductive layer 12B proximate to the base 10, so that light emitted by the light-emitting functional layer 14 in the direction toward the first electrode layer 12 is reflected by the reflective layer 12A. In addition, light emitted in a direction toward the second electrode layer 15 is transmitted. Herein, a material of the reflective layer 12A is not limited, as long as the reflective layer 12A may conduct electricity and may reflect light.

The material of the reflective layer 12A may be, for example, metal. A material of the transparent conductive layer 12B may be, for example, an oxide transparent conductive material, such as indium tin oxide (ITO).

It will be noted that the embodiments of the present disclosure do not limit a thickness of the transparent conductive layer 12B. For example, referring to FIG. 2, the thickness dl of the transparent conductive layer 12B is greater than 0 nm and less than or equal to approximately 200 nm. Herein, “approximately” may refer to, for example, a stated value (i.e., 200 nm), or it may also fluctuate by ten percent up and down on a basis of the stated value (i.e., 200 nm).

The embodiments of the present disclosure do not limit shapes of the reflective unit 121 and the transparent conductive unit 122, for example, they may be designed according to a required light-emitting area.

Shapes of orthographic projections of the reflective unit 121 and the transparent conductive unit 122 on the base 10 may be same or different.

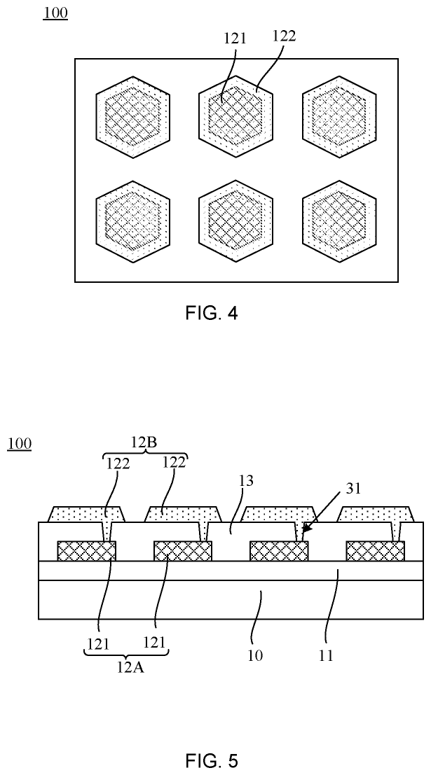

For example, as shown in FIG. 1, a shape of an orthographic projection of the reflective unit 121 on the base 10 and a shape of an orthographic projection of the transparent conductive unit 122 on the base 10 are both rectangular; or, as shown in FIG. 4, the shape of the orthographic projection of the reflective unit 121 on the base 10 and the shape of the orthographic projection of the transparent conductive unit 122 on the base 10 are both hexagons.

In some embodiments, the reflective units 121 and the transparent conductive units 122 are in one-to-one correspondence, and the transparent conductive unit 122 includes a flat surface 1221. Therefore, the reflective units 121 and the flat surface 1221 are also in one-to-one correspondence.

In some embodiments, as shown in FIG. 5, the display substrate 100 further includes an insulating layer 13 disposed between the reflective layer 12A and the transparent conductive layer 12B. The insulating layer 13 has via holes 31. The reflective unit 121 and the corresponding transparent conductive unit 122 are electrically connected through a via hole 31.

A material of the insulating layer 13 may be an organic insulating material or an inorganic insulating material. In a case where the material of the insulating layer 13 is the inorganic insulating material, an effect of preventing penetration of water vapor and oxygen may be improved, so that the reflective layer 12A may be well protected.

For example, the material of the insulating layer 13 is silicon oxide.

The embodiments of the present disclosure do not limit a size and shape of the via hole 31, as long as the transparent conductive unit 122 may be fully electrically connected to a corresponding reflective unit 121.

For example, an orthographic projection of the via hole 31 on the base 10 is a circle, and a diameter of the circle is greater than 0 nm and less than or equal to approximately 500 nm. Herein, “approximately” may refer to, for example, a stated value (i.e., 500 nm), or it may also fluctuate by ten percent up and down on a basis of the stated value (i.e., 500 nm).

Herein, a distance between the second electrode layer 15 and the reflective layer 12A in the light-emitting device is a length of a microcavity thereof. In this embodiment, the insulating layer 13 is provided between the reflective layer 12A and the transparent conductive layer 12B. In an aspect, the length of the microcavity of the light-emitting device may be adjusted by adjusting a thickness of the insulating layer 13, so that light may satisfy resonance conditions in the microcavity and then be strengthened, that is, a microcavity effect is generated. As a result, a microcavity resonance effect is used to improve a luminous efficiency of the light-emitting device. In another aspect, when metal materials whose chemical properties are prone to change such as aluminum are in direct contact with other conductive materials, chemical properties of the metal materials are prone to change, so that if the material of the reflective layer 12A includes the metal materials whose chemical properties are prone to change such as aluminum, the insulating layer 13 may be used to prevent a large-area direct contact between the reflective layer 12A and the transparent conductive layer 12B, thereby avoiding an increase in a contact resistance of the reflective layer 12A, a decrease in current, and affecting a display effect of the display substrate 100.

On this basis, for example, as shown in FIG. 5, when the transparent conductive layer 12B is manufactured, the material of each transparent conductive unit 122 passes through the via hole 31 to be in contact with a corresponding reflective unit 121, so that to the reflective units 121 are connected to the transparent conductive units 122 in a one-to-one correspondence.

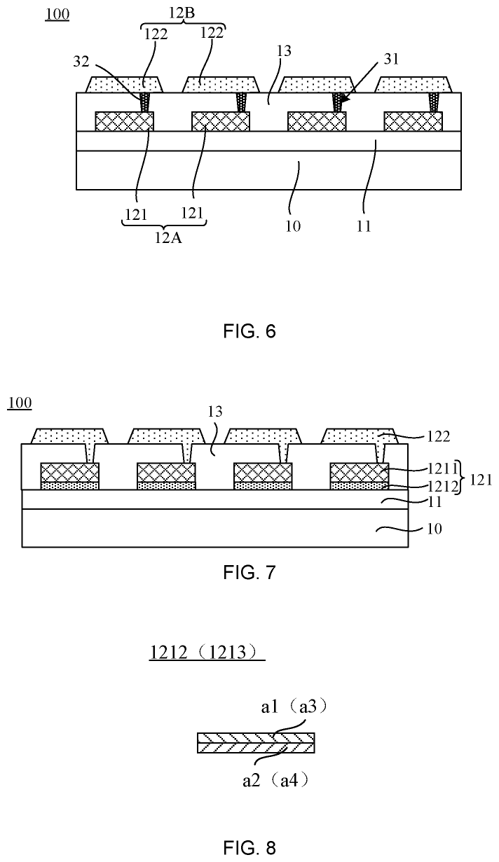

As another example, as shown in FIG. 6, the via hole 31 is filled with tungsten 32. Since tungsten 32 has almost no effect on a contact resistance of the metal materials whose chemical properties are prone to change such as aluminum, a stable electrical connection between the reflective unit 121 and the corresponding transparent conductive unit 122 may be achieved.

It will be noted that the embodiments of the present disclosure do not limit the thickness of the insulating layer 13, for example, the thickness of the insulating layer 13 may be designed according to factors such as the required length of the microcavity and insulating capacity. For example, a thickness of a portion of the insulating layer 13 located between the transparent conductive unit 122 and the corresponding reflective unit 121 is in a range from approximately 10 nm to approximately 500 nm. Herein, “approximately” may refer to, for example, a stated value (i.e., 10 nm and 500 nm), or it may also fluctuate by ten percent up and down on a basis of the stated value (i.e., 10 nm and 500 nm).

In the above example, since the thickness of the portion of the insulating layer 13 located between the transparent conductive unit 122 and the corresponding reflective unit 121 is set to be in the range from approximately 10 nm to approximately 500 nm, it is possible to avoid an overlarge thickness of the display substrate 100 due to an overlarge thickness of the insulating layer 13 on a basis of adjusting the length of the microcavity of the light-emitting device.

In some embodiments, as shown in FIG. 7, the reflective unit 121 includes a metal portion 1211.

On this basis, for example, a material of the metal portion 1211 includes at least one of aluminum, copper, or titanium nitride.

For example, the material of the metal portion 1211 may only include aluminum. Aluminum has a high reflectivity to light, which may improve display brightness without changing the current.

Of course, the material of the metal portion 1211 may also be other metals. For example, the material of the metal portion 1211 may include copper. Since a cost of copper is relatively low, the manufacturing cost of the display substrate may be saved. As another example, the material of the metal portion 1211 may also be titanium nitride or the like.

In some embodiments, as shown in FIG. 7, the reflective unit 121 further includes a first protective portion 1212 disposed on a side of the metal portion 1211 facing away from the transparent conductive layer. In this way, the first protective portion 1212 may be used to protect the metal portion 1211 to avoid water vapor and oxygen entering the metal portion 1211 from the side of the metal portion 1211 facing away from the transparent conductive layer, thereby preventing the metal portion 1211 from being oxidized.

A thickness of the first protective portion 1212 may be, for example, greater than 0 nm and less than or equal to approximately 200 nm. Herein, “approximately” may refer to, for example, a stated value (i.e., 200 nm), or it may also fluctuate by ten percent up and down on a basis of the stated value (i.e., 200 nm).

A material of the first protective portion 1212 may be, for example, a conductive material. In this way, the first protective portion 1212 may be used to be electrically connected to the pixel circuit layer 11 on the base 10, so that electrical signals sent by the pixel circuit layer 11 may sequentially flow through the first protective portion 1212, the metal portion 1211, and the transparent conductive units 122. As a result, the display substrate 100 may achieve a light-emitting display function. It will be understood that in a case where the insulating layer 13 is provided, the electrical signals flowing from the metal portion 1211 to the transparent conductive units 122 further needs to pass through the via holes 31 (e.g., the tungsten 32 filled in the via holes 31) before the electrical signals flow to the transparent conductive units 122.

It will be noted that the embodiments of the present disclosure do not limit a thickness and a material of the first protective portion 1212, as long as the first protective portion 1212 may be used to protect the metal portion 1211 and prevent the metal portion 1211 from being oxidized.

For example, referring to FIG. 8, the first protective portion 1212 includes a first protective sub-portion a1 and/or a second protective sub-portion a2. In a case where the first protective portion 1212 includes both the first protective sub-portion a1 and the second protective sub-layer a2, the first protective sub-portion a1 and the second protective sub-portion a2 are stacked in a thickness direction of the base 10.

A material of the first protective sub-portion a1 includes titanium, and a material of the second protective sub-portion a2 includes titanium nitride.

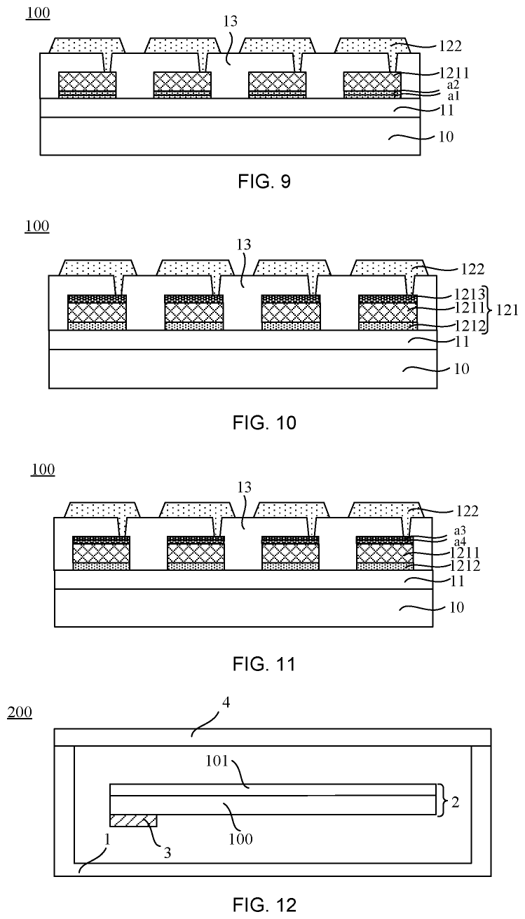

On this basis, for example, referring to FIG. 9, the second protective sub-portion a2 in the first protective portion 1212 is closer to the metal portion 1211 than the first protective sub-portion a1 in the first protective portion 1212. With this arrangement, the second protective sub-portion a2 made of titanium nitride material may be used to block mobility of metal ions (e.g., the metal materials whose chemical properties are prone to change such as aluminum) in the metal portion 1211, and the first protective sub-portion a1 made of titanium material may be used to improve adhesive performance between adjacent layers, thereby helping to improve stability and reliability of the display substrate 100.

In some embodiments, as shown in FIG. 10, the reflective unit 121 further includes a second protective portion 1213 disposed on a side of the metal portion 1211 proximate to the transparent conductive layer. In this way, the second protective portion 1213 may be used to protect the metal portion 1211 to avoid water vapor and oxygen entering the metal portion 1211 from the side of the metal portion 1211 proximate to the transparent conductive layer, thereby preventing the metal portion 1211 from being oxidized.

A thickness of the second protective portion 1213 may be, for example, greater than 0 nm and less than or equal to approximately 200 nm. Herein, “approximately” may refer to, for example, a stated value (i.e., 200 nm) or it may also fluctuate by ten percent up and down on a basis of the stated value (i.e., 200 nm).

A material of the second protective portion 1213 may be, for example, a conductive material. With this arrangement, the electrical signals flowing from the metal portion 1211 to the transparent conductive units 122 may be transmitted through the second protective portion 1213. In addition, in a case where the insulating layer 13 is provided, the electrical signals flowing from the metal portion 1211 to the transparent conductive units 122 needs to pass through the via holes 31 (e.g., the tungsten 32 filled in the via holes 31) after passing through the second protective portion 1213, and then may be transmitted to the transparent conductive units 122.

It will be noted that the embodiments of the present disclosure do not limit a thickness and a material of the second protective portion 1213, as long as the second protective portion 1213 may be used to protect the metal portion 1211 and prevent the metal portion 1211 from being oxidized.

For example, referring to FIG. 8, the second protective portion 1213 includes a third protective sub-portion a3 and a fourth protective sub-portion a4. In a case where the second protective portion 1213 includes both the third protective sub-portion a3 and the fourth protective sub-portion a4, the third protective sub-portion a3 and the fourth protective sub-portion a4 are stacked in the thickness direction of the base 10.

A material of the third protective sub-portion a3 includes titanium, and a material of the fourth protective sub-portion a4 includes titanium nitride.

On this basis, for example, referring to FIG. 11, the fourth protective sub-portion a4 in the second protective portion 1213 is closer to the metal portion 1211 than the third protective sub-portion a3 in the second protective portion 1213. With this arrangement, the fourth protective sub-portion a4 made of titanium nitride material may be used to block mobility of metal ions (e.g., the metal materials whose chemical properties are prone to change such as aluminum) in the metal portion 1211, and the third protective sub-portion a3 made of titanium material may be used to improve adhesive performance between adjacent layers, thereby helping to improve the stability and reliability of the display substrate 100.

It will be understood that the reflective unit 121 described above may include only the second protective layer 1213, or may include only the first protective layer 1212, or may simultaneously include the second protective layer 1213 and the first protective layer 1212.

Some embodiments of the present disclosure provide a display apparatus 200. As shown in FIG. 12, the display apparatus 200 includes the display substrate 100 to described in any of the foregoing embodiments.

The display apparatus 200 may be used as, for example, a mobile phone, a tablet computer, a personal digital assistant (PDA), and a vehicle-mounted computer. The embodiments of the present disclosure do not specifically limit a specific use of the display apparatus 200.

Beneficial effects that can be achieved by the display apparatus 200 provided by some embodiments of the present disclosure are the same as beneficial effects that can be achieved by the display substrate 100, and will not be described herein again.

For example, as shown in FIG. 12, the display apparatus 200 may include, for example, a frame 1, a display panel 2, a circuit board 3, a cover plate 4, a camera and other electronic accessories. The display panel 2 includes the display substrate 100 and an encapsulation layer 101.

In addition, the display apparatus 200 may be, for example, the OLED display apparatus, or the QLED display apparatus.

For example, a light exit direction of the display substrate 100 may be top-emitting, and the frame 1 may be a U-shaped frame. The display substrate 100 and the circuit board 3 are arranged in the frame 1. The cover plate 4 is disposed on a light exit side of the display panel 2, and the circuit board 3 is disposed on a side of the display panel 2 facing away from the cover plate 4.

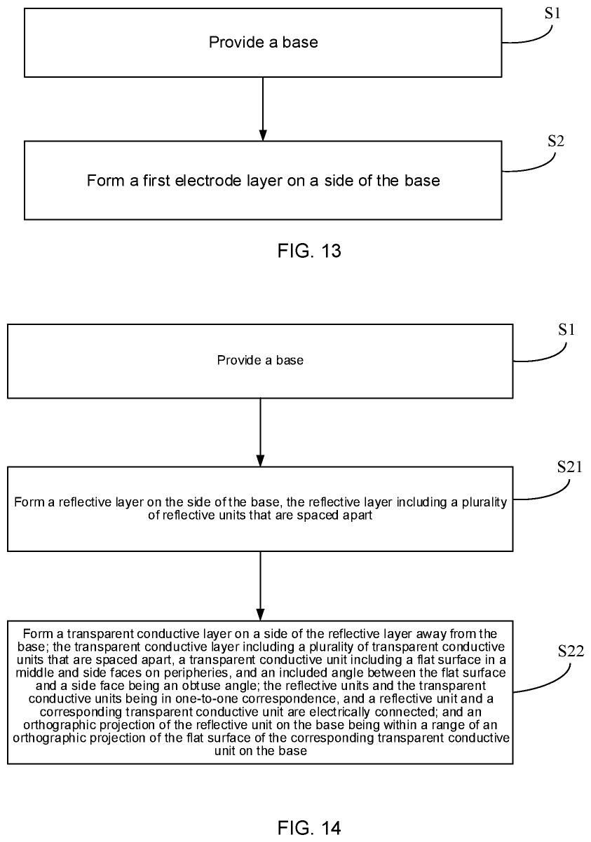

Some embodiments of the present disclosure provide a method of manufacturing a display substrate. Referring to FIGS. 1, 2 and 13, the method includes steps 1 and 2 (S1 and S2).

In S1, a base 10 is provided.

A material of the base 10 may be, for example, polyimide, glass, or silicon.

In S2, a first electrode layer 12 is formed on a side of the base 10.

As shown in FIG. 14, S2 includes steps 21 and 22 (S21 and S22).

In S21, a reflective layer 12A is formed on the side of the base 10, and the reflective layer 12A includes a plurality of reflective units 121 that are spaced apart.

In S22, a transparent conductive layer 12B is formed on a side of the reflective layer 12A away from the base 10, the transparent conductive layer 12B includes a plurality of transparent conductive units 122 that are spaced apart, a transparent conductive unit 122 includes a flat surface 1221 in a middle and side faces 1222 on peripheries, and an included angle between the flat surface 1221 and a side face 1222 is an obtuse angle; the reflective units 121 and the transparent conductive units 122 are in one-to-one correspondence, and a reflective unit and a corresponding transparent conductive unit are electrically connected; and an orthographic projection of the reflective unit 121 on the base 10 is within a range of an orthographic projection of the flat surface 1221 of the corresponding transparent conductive unit 122 on the base 10.

On this basis, for example, referring to FIG. 3, a light-emitting functional layer 14 and a second electrode layer 15 may also be sequentially formed on the base 10 on which the first electrode layer 12 is formed.

Through the above method, the orthographic projection of the reflective unit 12A on the base 10 is not beyond the orthographic projection of a corresponding flat surface 1221 on the base 10. In this way, when the light-emitting functional layer 14 emits light, light to the first electrode layer 12 in a direction perpendicular from the light-emitting functional layer 14 to the base 10 and a small amount of small-angle light in a direction toward the first electrode layer 12, both emitted by a portion of the light-emitting functional layer 14 that overlaps an orthographic projection of the reflective layer 12A on the base 10, may be reflected by the reflective layer 12A. Light emitted by a portion of the light-emitting functional layer 14 that does not overlap the reflective layer 12A may hardly be reflected by the reflective layer 12A. As a result, a problem of non-uniform light emission may be improved.

Moreover, when the light-emitting functional layer 14 emits light, large-angle light, emitted in the direction toward the first electrode layer 12 by the portion of the light-emitting functional layer 14 that overlaps the orthographic projection of the reflective layer 12A on the base 10 may hardly be reflected by the reflective layer 12A. Therefore, the pixel defining layer in the related art may be replaced, process steps of manufacturing the pixel defining layer may be omitted, and manufacturing process of the display substrate 100 may be simplified, which is beneficial to lower the manufacturing cost.

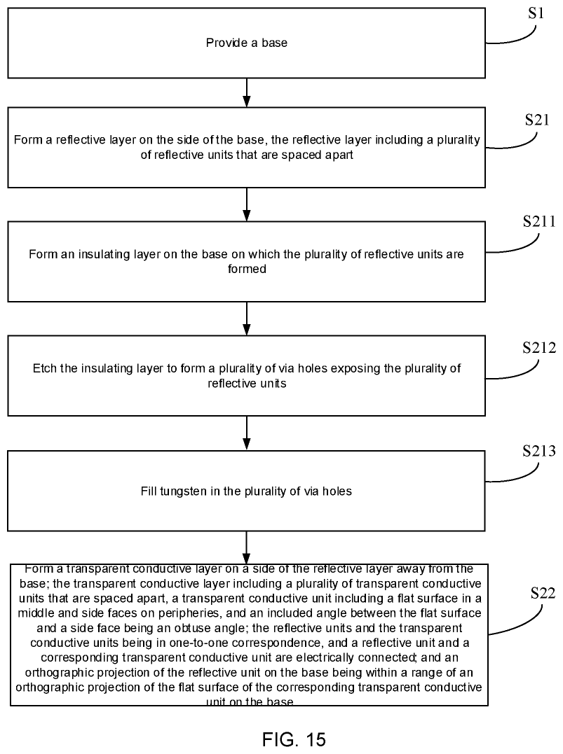

In some embodiments, as shown in FIG. 15, steps 211 to 213 (S211 to S213) are further provided between S21 and S22.

In S211, an insulating layer 13 is formed on the base 10 on which the plurality of reflective units 121 are formed.

A material of the insulating layer 13 may be, for example, silicon oxide.

In S212, the insulating layer 13 is etched to form a plurality of via holes 31 exposing the plurality of reflective units 121.

In S213, tungsten 32 is filled in the plurality of via holes 31. For example, as shown in FIG. 6, tungsten 32 may be filled in the plurality of via holes 31, so that a surface of a side of the insulating layer 13 proximate to the transparent conductive layer 12B is flat, which facilitates subsequent production of the transparent conductive layer 12B.

A material of the reflective units 121 may include metal materials whose chemical properties are prone to change such as aluminum. When the metal materials whose chemical properties are prone to change such as aluminum are in direct contact with other conductive materials, chemical properties of the metal materials are prone to change. Therefore, in a case where the material of the reflective units 121 includes the metal materials whose chemical properties are prone to change such as aluminum, the insulating layer 13 may be used to prevent a large-area direct contact between the reflective unit 121 and a corresponding transparent conductive unit 122, thereby avoiding an increase in a contact resistance of the reflective unit 121 and a decrease in current, and affecting a display effect of the display substrate 100. In addition, tungsten 32 is filled in the via holes 31. Since tungsten 32 has almost no effect on a contact resistance of the metal materials whose chemical properties are prone to change such as aluminum, a stable electrical connection between the reflective unit 121 and the corresponding transparent conductive unit 122 may be achieved.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display substrate, comprising:
a base; and
a first electrode layer disposed on a side of the base, and the first electrode layer including:
a transparent conductive layer including a plurality of transparent conductive units that are spaced apart, wherein a transparent conductive unit includes a flat surface in a middle and side faces on peripheries, and an included angle between the flat surface and a side face is an obtuse angle; and
a reflective layer located on a side of the transparent conductive layer proximate to the base, wherein the reflective layer includes a plurality of reflective units that are spaced apart; the reflective units and the transparent conductive units are in one-to-one correspondence, and a reflective unit and a corresponding transparent conductive unit are electrically connected; and an orthographic projection of the reflective unit on the base is within a range of an orthographic projection of the flat surface of the corresponding transparent conductive unit on the base.

2. The display substrate according to claim 1, wherein the first electrode layer further includes
an insulating layer disposed between the reflective layer and the transparent conductive layer, wherein
the insulating layer has a plurality of via holes; and each reflective unit and the corresponding transparent conductive unit are electrically connected through a via hole.

3. The display substrate according to claim 2, wherein a thickness of a portion of the insulating layer located between the transparent conductive unit and the corresponding reflective unit is in a range from approximately 10 nm to approximately 500 nm.

4. The display substrate according to claim 2, wherein the via hole is filled with tungsten.

5. The display substrate according to claim 1, wherein the reflective unit includes a metal portion.

6. The display substrate according to claim 5, wherein
a material of the metal portion includes at least one of aluminum, copper, or titanium nitride.

7. The display substrate according to claim 5, wherein the reflective unit further includes:
a first protective portion disposed on a side of the metal portion facing away from the transparent conductive layer.

8. The display substrate according to claim 7, wherein the first protective portion includes
a first protective sub-portion, and a material of the first protective sub-portion including titanium.

9. The display substrate according to claim 8, wherein the second protective sub-portion in the first protective portion is closer to the metal portion than the first protective sub-portion in the first protective portion, and/or the second protective sub-layer in the second protective layer is closer to the metal layer than the first protective sub-layer in the first protective layer.

10. The display substrate according to claim 1, wherein an included angle between any side face and the flat surface of the transparent conductive unit is greater than or equal to approximately 120°.

11. The display substrate according to claim 1, further comprising:
a light-emitting functional layer disposed on a side of the transparent conductive layer away from the reflective layer; and
a second electrode layer disposed on a side of the light-emitting functional layer away from the transparent conductive layer.

12. A display apparatus, comprising:
the display substrate according to claim 1.

13. A method of manufacturing a display substrate, comprising:
providing a base; and
forming a first electrode layer on a side of the base, wherein forming the first electrode layer on the side of the base includes:
forming a reflective layer on the side of the base, the reflective layer including a plurality of reflective units that are spaced apart; and
forming a transparent conductive layer on a side of the reflective layer away from the base; the transparent conductive layer including a plurality of transparent conductive units that are spaced apart; a transparent conductive unit including a flat surface in a middle and side faces on peripheries, and an included angle between the flat surface and a side face being an obtuse angle, wherein
the reflective units and the transparent conductive units are in one-to-one correspondence, and a reflective unit and a corresponding transparent conductive unit are electrically connected; and an orthographic projection of the reflective unit on the base is within a range of an orthographic projection of the flat surface of the corresponding transparent conductive unit on the base.

14. The method according to claim 13, wherein after forming the reflective layer and before forming the transparent conductive layer, the method further comprises:
forming an insulating layer on the base on which the plurality of reflective units are formed;
etching the insulating layer to form a plurality of via holes exposing the plurality of reflective units; and
filling tungsten in the plurality of via holes.

15. The display substrate according to claim 5, wherein the reflective unit further includes:
a second protective portion disposed on a side of the metal portion proximate to the transparent conductive layer.

16. The display substrate according to claim 15, wherein the second protective portion includes:
a third protective sub-portion, a material of the third protective sub-portion including titanium; and/or
a material of the fourth protective sub-portion including titanium nitride. a fourth protective sub-portion.

17. The display substrate according to claim 16, wherein the fourth protective sub-portion in the second protective portion is closer to the metal portion than the third protective sub-portion in the second protective portion.

18. The display apparatus according to claim 12, wherein the display apparatus is a top-emission display apparatus.
